(19) United States
(12) Patent Application Publication
(10) Pub. No.: US 2026/0028529 A1
(43) Pub. Date: Jan. 29, 2026

(54) ETCHING COMPOSITIONS

(71) Applicant: Fujifilm Electronic Materials U.S.A., Inc., N. Kingstown, RI (US)

(72) Inventors: Kohei Hayashi, Gilbert, AZ (US); Tomonori Takahashi, Shizuoka (JP)

(21) Appl. No.: 19/098,249

(22) Filed: Apr. 2, 2025

Related U.S. Application Data
(60) Provisional application No. 63/676,511, filed on Jul. 29, 2024.

(51) Int. Cl. C09K 13/08; H01L 21/02; H01L 21/3213

(52) U.S. Cl. CPC C09K 13/08; H01L 21/02068; H01L 21/32134

(57) ABSTRACT

The present disclosure provides etching compositions that can selectively etch TiN in the presence of a variety of other layers, such as, for example, W, AlOₓ, and interlayer dielectrics (ILD).

### CROSS-REFERENCE TO RELATED APPLICATION

The present application claims priority to U.S. Provisional Application Ser. No. 63/676,511, filed on Jul. 29, 2024, the contents of which are hereby incorporated by reference in their entirety.

### FIELD OF THE DISCLOSURE

The present disclosure relates to etching compositions and processes of using etching compositions. In particular, the present disclosure relates to etching compositions that can selectively etch titanium nitride (TiN) layers without substantially removing other layers on a substrate.

### BACKGROUND OF THE DISCLOSURE

The semiconductor industry is rapidly decreasing the dimensions and increasing the density of electronic circuitry and electronic components in microelectronic devices, silicon chips, liquid crystal displays, MEMS (Micro Electro Mechanical Systems), printed wiring boards, and the like. The integrated circuits within them are being layered or stacked with constantly decreasing thicknesses of the insulating layer between each circuitry layer and smaller and smaller feature sizes. As the feature sizes have shrunk, patterns have become smaller, and device performance parameters tighter and more robust. As a result, various issues which heretofore could be tolerated, can no longer be tolerated or have become more of an issue due to the smaller feature size.

In the production of advanced integrated circuits, to minimize problems associated with the higher density and to optimize performance, both high k and low k insulators, and assorted barrier layer materials have been employed.

Titanium nitride (TiN) is utilized for semiconductor devices, liquid crystal displays, MEMS (Micro Electro Mechanical Systems), printed wiring boards and the like, and as ground layers and cap layers for precious metal, aluminum (Al) and copper (Cu) wiring. In semiconductor devices, it may be used as a barrier metal, a hard mask, or a gate metal. In the construction of devices for these applications, TiN frequently needs to be etched. In the various types of uses and device environments of TiN, other layers are in contact with or otherwise exposed at the same time as the TiN is etched. Highly selective etching of the TiN in the presence of these other materials (e.g., metal conductors, dielectric, and hard marks) is mandatory for device yield and long life.

### SUMMARY OF THE DISCLOSURE

The present disclosure provides etching compositions that can selectively etch TiN in the presence of a variety of other layers, such as, for example, W, AlOₓ, and interlayer dielectrics (ILD).

In some embodiments, the disclosure features compositions including: at least one oxidizing agent, at least one chelating agent, at least one metal corrosion inhibitor, at least one pH adjusting agent, wherein the pH adjusting agent is aminoalcohol, and water, wherein the composition has a pH less than about 7.

In some embodiments, the at least one oxidizing agent includes hydrogen peroxide. In some embodiments, the oxidizing agent is present in the composition from about 10 percent to about 40 percent by weight.

In some embodiments, the at least one chelating agent includes an organophosphorus compound. In some embodiments, the organophosphorus compound is a phosphonic acid. In some embodiments, the phosphonic acid is 1-hydroxyethane-1,1-diphosphonic acid.

In some embodiments, the chelating agent is a polyaminocarboxylic acid.

In some embodiments, the compositions of the disclosure include from about 0.1 percent to about 5 percent by weight of the at least one chelating agent.

In some embodiments, the at least one metal corrosion inhibitor is a quaternary ammonium salt. In some embodiments, the quaternary ammonium salt is benzethonium chloride.

In some embodiments, the at least one metal corrosion inhibitor is a biguanide.

In some embodiments, the biguanide is chlorhexidine digluconate.

In some embodiments, the compositions of the disclosure include from about 0.05 percent to about 1 percent by weight of the at least one metal corrosion inhibitor.

In some embodiments, the compositions of the disclosure include aminoalcohols bearing one hydroxyl moiety, two hydroxyl moieties, or three hydroxyl moieties.

In some embodiments, the aminoalcohol is monoethanolamine, diethanolamine, triethanolamine, 4-amino-1-butanol, 2-(2-aminoethoxy)ethanol, 3-amino-1-propanol, 2-amino-1-propanol, 1-amino-2-propanol, 2-amino-1-butanol, 2-amino-2-methyl-1-propanol, 2-(2-aminoethoxy)propanol, 5-amino-1-pentanol, 2-amino-1-pentanol, 2-amino-3-methyl-1-butanol, 2-amino-1-hexanol, isoleucinol, leucinol, 1-amino-1-cyclopentanemethanol, trans-2-aminocyclohexanol, trans-4-aminocyclohexanol, 3-aminomethyl-3,5,5-trimethylcyclohexanol, 1-aminomethyl-1-cyclohexanol, 6-amino-1-hexanol, 6-amino-2-methyl-2-heptanol, 4-amino-4-(3-hydroxypropyl)-1,7-heptanediol, serinol, 3-amino-1,2-propanediol, N-(3-aminopropyl)-diethanolamine, 2-amino-2-ethyl-1,3-propanediol, 2-amino-2-methyl-1,3-propanediol, tris(hydroxymethyl)aminomethane, 1-amino-1-deoxy-D-sorbitol, or (hydroxyethoxyethyl)amine.

In some embodiments, the pH adjusting agent is present in the compositions of the disclosure from about 1 weight percent to about 5 weight percent.

In some embodiments, the compositions of the disclosure include from about 50 percent to about 80 percent of water.

In some embodiments, the compositions of the disclosure further include a fluorine compound. In some embodiments, the fluorine compound is HF.

In some embodiments, the compositions of the disclosure have a pH between about 5.0 and about 6.0. In some embodiments, the compositions of the disclosure have a pH between about 4.5 and about 6.0.

In other embodiments of the disclosure there are provided methods, including contacting a semiconductor substrate containing TiN features with a composition of the disclosure, thereby removing the TiN features.

In some embodiments, the methods further include rinsing the semiconductor substrate with a rinse solvent after the contacting step. In some embodiments, the methods further include drying the semiconductor substrate after the rinsing step.

In some embodiments, the methods do not substantially remove W, Co, SiN, or Cu in the semiconductor substrate. In some embodiments, the methods do not substantially remove W. In some embodiments, the methods do not substantially remove ILD (interlevel dielectric) layers.

In some embodiments there are provided articles formed by the methods of the disclosure, wherein the article is a semiconductor device. In some embodiments, the semiconductor device is an integrated circuit.

### DETAILED DESCRIPTION OF THE DISCLOSURE

As defined herein, unless otherwise noted, all percentages expressed should be understood to be percentages by weight to the total weight of the composition. Unless otherwise noted, ambient temperature is defined to be between about 16 and about 27 degrees Celsius (° C.).

As defined herein, a “water-soluble” substance (e.g., a water-soluble alcohol, ketone, ester, ether, and the like) refers to a substance having a solubility of at least 0.5% by weight (e.g., at least 1% by weight or at least 5% by weight) in water at 25° C.

In general, the disclosure features an etching composition (e.g., an etching composition for selectively removing TiN) that includes at least one oxidizing agent, at least one chelating agent, at least one metal corrosion inhibitor, at least one pH adjusting agent, wherein the pH adjusting agent is aminoalcohol, and water, wherein the composition has a pH less than about 7. In some embodiments, the etching composition contains these five types of components only.

The etching composition of this disclosure can include at least one (e.g., two, three, or four) oxidizing agent suitable for use in microelectronic applications. Examples of suitable oxidizing agents include, but are not limited to, oxidizing acids or salts thereof (e.g., nitric acid, permanganic acid, or potassium permanganate), peroxides (e.g., hydrogen peroxide, dialkylperoxides, urea hydrogen peroxide), persulfonic acid (e.g., hexafluoropropanepersulfonic acid, methanepersulfonic acid, trifluoromethanepersulfonic acid, or p-toluenepersulfonic acid) and salts thereof, ozone, percarbonic acids (e.g., peracetic acid) and salts thereof, perphosphoric acid and salts thereof, persulfuric acid and salts thereof (e.g., ammonium persulfate or tetramethylammonium persulfate), perchloric acid and salts thereof (e.g., ammonium perchlorate, sodium perchlorate, or tetramethylammonium perchlorate)), and periodic acid and salts thereof (e.g., periodic acid, ammonium periodate, or tetramethylammonium periodate). These oxidizing agents can be used singly or in combination.

In some embodiments, the at least one oxidizing agent can be from at least about 10% by weight (e.g., at least about 12% by weight, at least about 14% by weight, at least about 16% by weight, at least about 18% by weight, at least about 20% by weight, at least about 22% by weight, at least about 24% by weight, or at least about 26% by weight) to at most about 40% by weight (e.g., at most about 38 wt %, at most about 36 wt %, at most about 34 wt %, at most about 32 wt %, at most about 30 wt %, or at most about 28 wt %) of the total weight of the etching composition of this disclosure. Without wishing to be bound by theory, it is believed that the oxidizing agent can facilitate and enhance the removal of TiN on a semiconductor substrate (e.g., by forming a TiOx type material that can be dissolved in the etching composition).

In general, the etching composition of this disclosure can include at least one (e.g., two, three, or four) chelating agent. In some embodiments, the chelating agent is organophosphorus compound. In some embodiments, the organophosphorus compound is a phosphonic acid. Phosphonic acids contemplated for use include those of formulas (I) and (II):

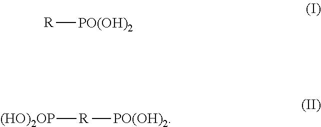

In formula (I), R is H, C₁-C₁₀ alkyl, C₁-C₁₀ substituted alkyl, or aryl. Exemplary substituents on the C₁-C₁₀ alkyl or aryl include hydroxyl or amino.

In formula (II), R is C₁-C₁₀ alkylene, C₁-C₁₀ substituted alkylene, or arylene. Exemplary substituents on the C₁-C₁₀ alkylene or arylene include hydroxyl or amino.

In some embodiments, the phosphonic acid is 1-hydroxyethane-1,1-diphosphonic acid.

In some embodiments, the chelating agent is a polyaminocarboxylic acid. Polyaninopolycarboxylic acid chelating agents include, but are not limited to, butylenediaminetetraacetic acid diethylenetriaminepentaacetic acid (DTPA), ethylenediaminetetrapropionic acid, triethylenetetrarninehexaacetic acid, 1,3-diamino-2-hydroxypropane-N,N,N′,N′-tetraacetic acid, propylenediaminetetraacetic acid, ethylenediaminetetraacetic acid (EDTA), trans-1,2-diaminocyclohexane tetraacetic acid, ethylendiamine diacetic acid, ethylendiamine dipropionic acid, 1,6-hexamethylene-diamine-N,N,N′N′-tetraacetic acid, N,N-bis(2-hydroxybenzyl)ethylenediamine-N,N-diacetic acid, diaminopropane tetraacetic acid, 1,4,7,10-tetraazacyclododecane-tetraacetic acid, diaminopropanol tetraacetic acid, and (hydroxyethyl)ethylenediaminetriacetic acid.

In some embodiments, the at least one chelating agent can be from at least about 0.5% by weight (e.g., at least about 0.07% by weight, at least about 0.09% by weight, at least about 1.1% by weight, at least about 1.3% by weight, at least about 1.5% by weight, or at least about 1.7% by weight) to at most about 5% by weight (e.g., at most about 4.5 wt %, at most about 4 wt %, at most about 3.5 wt %, at most about 3 wt %, at most about 2.5 wt %, or at most about 2 wt %) of total weight of the etching composition of this disclosure. Without wishing to be bound by theory, it is believed that one function (but not necessarily the only function) of the chelator is capturing trace metals in the etching composition and thereby extending peroxide shelf life by preventing its decomposition by reaction with the trace metal.

In general, the etching composition of this disclosure can include at least one (e.g., two, three, or four) metal corrosion inhibitor. Examples of corrosion inhibitors include quaternary ammonium salts such as quarternary ammonium halides or quaternary ammonium hydroxides. Quaternary ammonium hydroxides contemplated for use include tetraalkylammonium hydroxides. Examples of suitable tetraalkylammonium hydroxides include tetramethylammonium hydroxide (TMAH), tetraethylammonium hydroxide, tetrapropylammonium hydroxide, tetrabutylammonium hydroxide, benzyltrimethylammonium hydroxide (BTMAH), methyltriethylammonium hydroxide, ethyltrimethylammonium hydroxide (ETMAH), dimethyldiethylammonium hydroxide, 2-hydroxyethyltrimethylammonium hydroxide, tetraethanolammonium hydroxide, benzyltriethylammonium hydroxide, benzyltributylammonium hydroxide, and hexadecyltrimethylammonium hydroxide.

In some embodiments, the at least one metal corrosion inhibitor is a quaternary ammonium chloride. In certain embodiments, the quaternary ammonium halide is benzethonium chloride.

In some embodiments, the at least one metal corrosion inhibitor is a biguanide. In some embodiments, the biguanide is a bisbiguanide. In some embodiments, the bisbiguanide is chlorhexidine gluconate.

In some embodiments, the at least one metal corrosion inhibitor can be from at least about 10 ppm or about 0.0001% by weight (e.g., at least about 0.01% by weight, at least about 0.02% by weight, at least about 0.05% by weight, at least about 0.1% by weight, at least about 0.2% by weight, or at least about 0.5% by weight) to at most about 3% by weight (e.g., at most about 2.5 wt %, at most about 2 wt %, at most about 1.5 wt %, at most about 1 wt %, at most about 0.8 wt %, or at most about 0.5 wt %) of total weight of the etching composition of this disclosure.

In some embodiments, the compositions of the disclosure include aminoalcohols bearing one hydroxyl moiety, two hydroxyl moieties, or three hydroxyl moieties.

In some embodiments, the aminoalcohol is monoethanolamine, diethanolamine, triethanolamine, 4-amino-1-butanol, 2-(2-aminoethoxy)ethanol, 3-amino-1-propanol, 2-amino-1-propanol, 1-amino-2-propanol, 2-amino-1-butanol, 2-amino-2-methyl-1-propanol, 2-(2-aminoethoxy)propanol, 5-amino-1-pentanol, 2-amino-1-pentanol, 2-amino-3-methyl-1-butanol, 2-amino-1-hexanol, isoleucinol, leucinol, 1-amino-1-cyclopentanemethanol, trans-2-aminocyclohexanol, trans-4-aminocyclohexanol, 3-aminomethyl-3,5,5-trimethylcyclohexanol, 1-aminomethyl-1-cyclohexanol, 6-amino-1-hexanol, 6-amino-2-methyl-2-heptanol, 4-amino-4-(3-hydroxypropyl)-1,7-heptanediol, serinol, 3-amino-1,2-propanediol, N-(3-aminopropyl)-diethanolamine, 2-amino-2-ethyl-1,3-propanediol, 2-amino-2-methyl-1,3-propanediol, tris(hydroxymethyl)aminomethane, 1-amino-1-deoxy-D-sorbitol, or (hydroxyethoxyethyl)amine.

In some embodiments, the at least one aminoalcohol can be from at least about 1% by weight (e.g., at least about 1.2% by weight, at least about 1.4% by weight, at least about 1.6% by weight, at least about 1.8% by weight, at least about 2% by weight, or at least about 2.2% by weight) to at most about 5% by weight (e.g., at most about 4.8 wt %, at most about 4.6 wt %, at most about 4.2 wt %, at most about 4 wt %, at most about 3.8 wt %, or at most about 3.6 wt %) of total weight of the etching composition of this disclosure.

In general, the etching composition of this disclosure can include water as a solvent. In some embodiments, the water can be de-ionized and ultra-pure, contain no organic contaminants and have a minimum resistivity of about 4 to about 17 mega Ohms, or at least about 17 mega Ohms. In some embodiments, the water is in an amount of from at least about 60 wt % (e.g., at least about 65% by weight, at least about 70% by weight, at least about 75% by weight, at least about 80% by weight, at least about 85% by weight, at least about 90% by weight, or at least about 95% by weight) to at most about 98 wt % (e.g., at most about 97 wt %, at most about 95 wt %, at most about 90 wt %, at most about 85 wt %, at most about 80 wt %, at most about 75 wt %, or at most about 70 wt %) of the etching composition. Without wishing to be bound by theory, it is believed that the etching composition of this disclosure should include a certain level of water (e.g., at least about 60 wt %) to keep all other components solubilized and to avoid reduction in the etching performance.

In some embodiments, the etching composition of this disclosure can optionally further include at least one (e.g., two, three, or four) organic solvent. The organic solvent can be selected from the group consisting of water soluble alcohols, water soluble ketones, water soluble esters, and water soluble ethers.

Classes of water soluble alcohols include, but are not limited to, alkane diols (including, but not limited to, alkylene glycols), glycols, alkoxyalcohols (including, but not limited to, glycol monoethers), saturated aliphatic monohydric alcohols, unsaturated non-aromatic monohydric alcohols, and low molecular weight alcohols containing a ring structure.

Examples of water soluble alkane diols include, but are not limited to, 2-methyl-1,3-propanediol, 1,3-propanediol, 2,2-dimethyl-1,3-diol, 1,4-butanediol, 1,3-butanediol, 1,2-butanediol, 2,3-butanediol, pinacol, and alkylene glycols.

Examples of water soluble alkylene glycols include, but are not limited to, ethylene glycol, propylene glycol, diethylene glycol, dipropylene glycol, triethylene glycol and tetraethylene glycol.

Examples of water soluble alkoxyalcohols include, but are not limited to, 3-methoxy-3-methyl-1-butanol, 3-methoxy-1-butanol, 1-methoxy-2-butanol, and water soluble glycol monoethers.

Examples of water soluble glycol monoethers include, but are not limited to, ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol monobutyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of water soluble saturated aliphatic monohydric alcohols include, but are not limited to methanol, ethanol, n-propyl alcohol, isopropyl alcohol, 1-butanol, 2-butanol, isobutyl alcohol, tert-butyl alcohol, 2-pentanol, t-pentyl alcohol, and 1-hexanol.

Examples of water soluble unsaturated non-aromatic monohydric alcohols include, but are not limited to allyl alcohol, propargyl alcohol, 2-butenyl alcohol, 3-butenyl alcohol, and 4-penten-2-ol.

Examples of water soluble, low molecular weight alcohols containing a ring structure include, but are not limited, to tetrahydrofurfuryl alcohol, furfuryl alcohol, and 1,3-cyclopentanediol.

Examples of water soluble ketones include, but are not limited to, acetone, propanone, cyclobutanone, cyclopentanone, cyclohexanone, diacetone alcohol, 2-butanone, 2,5-hexanedione, 1,4-cyclohexanedione, 3-hydroxyacetophenone, 1,3-cyclohexanedione, and cyclohexanone.

Examples of water soluble esters include, but are not limited to, ethyl acetate, glycol monoesters (such as ethylene glycol monoacetate and diethyleneglycol monoacetate), and glycol monoether monoesters (such as propylene glycol monomethyl ether acetate, ethylene glycol monomethyl ether acetate, propylene glycol monoethyl ether acetate, and ethylene glycol monoethylether acetate).

In some embodiments, the at least one organic solvent can be from at least about 2 wt % (e.g., at least about 4% by weight, at least about 5% by weight, at least about 6% by weight, at least about 8% by weight, or at least about 10% by weight) to at most about 20 wt % (e.g., at most about 18 wt %, at most about 16 wt %, at most about 15 wt %, at most about 14 wt %, at most about 12 wt %, or at most about 10 wt %) of the total weight of the etching composition.

In some embodiments, the etching composition of this disclosure can optionally further include at least one (e.g., two, three, or four) pH adjusting agents, such as an acid or a base. In some embodiments, the pH adjusting agent can be a base free of a metal ion. Suitable metal ion free bases include quaternary ammonium hydroxides (e.g., a tetraalkylammonium hydroxide such as TMAH), ammonium hydroxide, monoamines (including alkanolamines), amidines (such as 1,8-diazabicyclo[5.4.0]-7-undecene (DBU) and 1,5-diazabicyclo[4.3.0]-5-nonene (DBN)), and guanidine salts (such as guanidine carbonate). In some embodiments, the base is not a quaternary ammonium hydroxide (e.g., a tetraalkylammonium hydroxide such as TMAH).

In some embodiments, the pH adjusting agent can be an organic acid, such as a sulfonic acid (e.g., methanesulfonic acid, trifluoromethanesulfonic acid, and p-toluenesulfonic acid).

In some embodiments, when the pH adjusting agent is an organic acid, the organic acid is not an unsaturated carboxylic acid described above or a saturated carboxylic acid containing one or more (e.g., two, three, or four) carboxyl groups (e.g., citric acid, oxalic acid, or acetic acid). In some embodiments, the pH adjusting agent is not a hydrogen halide.

In general, the pH adjusting agent in the etching composition of this disclosure can be in an amount sufficient to adjust the pH of the etching composition to a desired value. In some embodiments, the pH adjusting agent can be from at least about 0.01 wt % (e.g., at least about 0.05 wt %, at least about 0.1 wt %, at least about 0.5 wt %, at least about 1 wt %, or at least about 2 wt %) to at most about 6 wt % (e.g., at most about 5.5 wt %, at most about 5 wt %, at most about 4 wt %, at most about 3 wt %, at most about 2 wt %, or at most about 1 wt %) of the total weight of the etching composition.

In some embodiments, the etching composition of this disclosure can have a pH of at least about 4 (e.g., at least about 4.2, at least about 4.4, at least about 4.5, at least about 4.6, at least about 4.8, at least about 5, at least about 5.2, or at least about 5.4) and/or at most about 7 (e.g., at most about 6.8, at most about 6.6, at most about 6.4, at most about 6.2, at most about 6.0, at most about 5.8, or at most about 5.6). Without wishing to be bound by theory, it is believed that an etching composition having a pH higher than 7 diminishes bath-life, due to decomposition of one or more components. Further, it is believed that an etching composition having a pH lower than 4 could prevent certain components (e.g., a metal corrosion inhibitor) in the composition from functioning, or decompose certain components in the composition due to strong acidity.

In addition, in some embodiments, the etching composition of the present disclosure may contain additives such as, additional corrosion inhibitors, surfactants, additional organic solvents, biocides, and defoaming agents as optional components. Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants may be cationic, anionic, nonionic or amphoteric.

In some embodiments, the etching composition of the present disclosure may contain fluorine-containing additives, such as, for example, HF, ammonia fluoride, hexafluorosilicate or hexafluorophosphoric acid.

In general, the etching composition of the present disclosure has TiN/W etching selectivity (i.e., a high ratio of TiN etch rate over tungsten etch rate). In some embodiments, the etching composition can have a TiN/W etch selectivity of at least about 20 (e.g., at least about 40, at least about 60, at least about 80, at least about 90, and/or at least about 100).

In general, the etching composition of the present disclosure have TiN/dielectric material (e.g., SiN, polysilicon, high k dielectrics, AlOx, SiOx, or SiCO) etch selectivity (i.e., a high ratio of TiN etch rate over dielectric material etch rate). In some embodiments, the etching composition can have a TiN/dielectric material etch selectivity of at least about 2 (e.g., at least about 3, at least about 4, at least about 5, at least about 6, at least about 7, at least about 8, at least about 9, at least about 10, at least about 15, at least about 20, at least about 30, at least about 40, or at least about 50) and/or at most about 250 (e.g., at most about 240, at most about 230, at most about 220, and/or at most about 210).

In some embodiments, the etching composition of the present disclosure may specifically exclude one or more of the additive components, in any combination if more than one. Such components are selected from the group consisting of organic solvents, pH adjusting agents, polymers (e.g., cationic or anionic polymers), oxygen scavengers, quaternary ammonium salts or quaternary ammonium hydroxides, amines, alkaline bases (such as NaOH, KOH, and LiOH), surfactants other than a defoamer, a defoamer, fluoride containing compounds, abrasives (e.g., cationic or anionic abrasives), silicates, hydroxycarboxylic acids (e.g., those containing more than two hydroxyl groups), carboxylic and polycarboxylic acids (e.g., those containing or lacking amino groups), silanes (e.g., alkoxysilanes), cyclic compounds (e.g., azoles (such as diazoles, triazoles, or tetrazoles), triazines, and cyclic compounds containing at least two rings, such as substituted or unsubstituted naphthalenes, or substituted or unsubstituted biphenylethers), buffering agents, non-azole corrosion inhibitors, halide salts, and metal salts (e.g., metal halides).

The etching composition of this disclosure can be prepared by simply mixing the components together, or can be prepared by blending two compositions in a kit. The first composition in the kit can be an aqueous solution of an oxidizing agent (e.g., H₂O₂).

The second composition in the kit can contain the remaining components of the etching composition of this disclosure at predetermined ratios in a concentrated form such that the blending of the two compositions will yield a desired etching composition of the disclosure.

In some embodiments, the present disclosure features a method of etching a semiconductor substrate containing at least one TiN feature (e.g., a TiN film or layer). In some embodiments, the TiN feature can be a liner or barrier (e.g., having a thickness of about 1 nm). In some embodiments, the TiN feature is a TiN hard mask.

In other embodiments of the disclosure there are provided methods, including contacting a semiconductor substrate containing TiN features with a composition of the disclosure, thereby removing the TiN features.

In some embodiments, the methods further include rinsing the semiconductor substrate with a rinse solvent after the contacting step. In some embodiments, the methods further include drying the semiconductor substrate after the rinsing step.

In some embodiments, the methods do not substantially remove W, Co, SiN, or Cu in the semiconductor substrate. In some embodiments, the methods do not substantially remove ILD (interlevel dielectric) layers.

In some embodiments, there are provided articles formed by the methods of the disclosure, wherein the article is a semiconductor device. In some embodiments, the semiconductor device is an integrated circuit.

Semiconductor substrates described herein (e.g., wafers) typically are constructed of silicon, silicon germanium, Group III-V compounds such as GaAs, or any combination thereof. The semiconductor substrates can additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, silicon, titanium nitride, tantalum nitride, and tungsten. The semiconductor substrates may also contain layers of interlayer dielectrics, polysilicon, silicon oxide, silicon nitride, silicon carbide, titanium oxide, and carbon doped silicon oxides.

A semiconductor substrate can be contacted with the etching composition by any suitable method, such as placing the etching composition into a tank and immersing and/or submerging the semiconductor substrate into the etching composition, spraying the etching composition onto the semiconductor substrate, streaming the etching composition onto the semiconductor substrate, or any combinations thereof.

The etching composition of the present disclosure can be effectively used up to a temperature of about 85° C. (e.g., from about 20° C. to about 80° C., from about 55° C. to about 65° C., or from about 60° C. to about 65° C.). The etch rates of TiN increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in an immersion batch type process, a suitable time range is, for example, up to about 10 minutes (e.g., from about 1 minute to about 7 minutes, from about 1 minute to about 5 minutes, or from about 2 minutes to about 4 minutes). Etching times for a single wafer process can range from about 30 seconds to about 5 minutes (e.g., from about 30 seconds to about 4 minutes, from about 1 minute to about 3 minutes, or from about 1 minute to about 2 minutes).

To further promote the etching ability of the etching composition of the present disclosure, mechanical agitation means can be employed. Examples of suitable agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

Subsequent to the etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate and propylene glycol monomethyl ether acetate. Alternatively, or in addition, aqueous rinses with pH>8 (such as dilute aqueous ammonium hydroxide) can be employed. Examples of rinse solvents include, but are not limited to, dilute aqueous ammonium hydroxide, DI water, methanol, ethanol, and isopropyl alcohol. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is between 16° C. and 27° C.

Optionally, the semiconductor substrate is dried after the rinsing step. Any suitable drying means known in the art can be employed. Examples of suitable drying means include spin drying, flowing a dry gas across the semiconductor substrate, heating the semiconductor substrate with a heating means such as a hotplate or infrared lamp, Marangoni drying, rotagoni drying, isopropyl alcohol (IPA) drying or any combinations thereof. Drying times will be dependent on the specific method employed but are typically on the order of 30 seconds up to several minutes.

The present disclosure is illustrated in more detail with reference to the following examples, which are for illustrative purposes and should not be construed as limiting the scope of the present disclosure.

### Examples

Any percentages listed are by weight (wt %) unless otherwise specified. Controlled stirring during testing was done with a 1 inch stirring bar at 300 rpm unless otherwise noted.

### General Procedure 1

### Formulation Blending

Samples of etching compositions were prepared by adding, while stirring, to the calculated amount of the solvent the remaining components of the formulation. After a uniform solution was achieved, optional additives, if used, were added.

### General Procedure 2

### Materials and Methods

Blanket test coupons were evaluated for etching and materials compatibility in the test solutions prepared by General Procedure 1 according to the procedures described in General Procedure 3.

Blanket film etch rate measurements on films were carried out using commercially available unpatterned 300 mm diameter wafers that were diced into 0.5″×1.0″ test coupons for evaluation. Primary blanket film materials used for testing included (1) a TiN film of about 250 Å thickness deposited on a silicon substrate, and (2) a W film of about 1000 Å thickness deposited on a silicon substrate, (3) a SiN film of about 100 Å thickness deposited on a silicon substrate, (4) a AlOx film of about 50 Å thickness deposited on a silicon substrate, and a SiOx film of about 1000 Å thickness deposited on a silicon substrate.

The blanket film test coupons were measured for pre-treatment and post-treatment thickness to determine blanket film etch rates. For the TiN, SiN, AlOx, and SiOx films, the film thickness was measured pre-treatment and post-treatment by Ellipsometry using a Woollam VASE. For the W films, the film thickness was measured pre-treatment and post-treatment by Sheet resistance measurement (Filmetrics R50-4PP).

### General Procedure 3

Etching Evaluation with Beaker Test

All blanket film etch testing was carried out at 41° C. (FE-11) or 50° C. (others). in a 600 mL glass beaker containing 200 g of a sample solution with continuous stirring at 250 rpm, with the Parafilm® cover in place at all times to minimize evaporative losses. All blanket test coupons having a blanket dielectric film exposed on one side to the sample solution were diced by diamond scribe into 0.5″×1.0″ square test coupon size for beaker scale testing. Each individual test coupon was held into position using a single 4″ long, locking plastic tweezers clip. The test coupon, held on one edge by the locking tweezers clip, was suspended into the 600 mL glass beaker and immersed into the 200 g test solution while the solution was stirred continuously at 250 rpm at 41° C. (FE-11) or 50° C. (others). Immediately after each sample coupon was placed into the stirred solution, the top of the 600 mL HDPE beaker was covered and resealed with Parafilm®. The test coupons were held static in the stirred solution until the treatment time (as described in General Procedure 3A) had elapsed. After the treatment time in the test solution had elapsed, the sample coupons were immediately removed from the 600 mL glass beaker and rinsed according to General Procedure 3A. After the final IPA rinse step, all test coupons were subject to a filtered nitrogen gas blow off step using a hand held nitrogen gas blower which forcefully removed all traces of IPA to produce a final dry sample for test measurements.

### General Procedure 3A (Blanket Test Coupons)

Immediately after a treatment time of 3 minutes according to General Procedure 3, the coupon was immersed in a 300 mL volume of IPA for 15 seconds with mild agitation, which was followed by 300 mL of IPA for 15 seconds with mild agitation, and a final rinse in 300 mL of DI water for 15 seconds with mild agitation. The processing was completed according to General Procedure 3.

TABLE 1

| | | | | | | | | | | | | AlOx | SiOx | |
|---|---|---|---|---|---|---|---|---|---|---|---|---|---|---|
| Formu- | | | | | | | | | Etching | TiN ER | W ER | ER | ER | TiN/W |
| lation | H₂O₂ | BECl | CHG | HEDP | Aminoalcohol | Water | pH | Total | temp. | (Å/min) | (Å/min) | (Å/min) | (Å/min) | selectivity) |
| FE-1 | 27% | 0.1% | 15 ppm | 1.9% | Tris | remainder | 5.0 | 100% | 50 C. | 47.1 | 0.4 | <1 | <1 | 117.8 |
| | | | | | 2.8% | | | | | | | | | |
| FE-2 | 27% | 0.1% | 15 ppm | 1.9% | Tris | remainder | 5.5 | 100% | 50 C. | 61.8 | 1.2 | <1 | <1 | 51.5 |
| | | | | | 3.1% | | | | | | | | | |
| FE-3 | 27% | 0.1% | 15 ppm | 1.9% | AMPD | remainder | 5.5 | 100% | 50 C. | 51 | 0.8 | <1 | <1 | 63.8 |
| | | | | | 2.7% | | | | | | | | | |
| FE-4 | 27% | 0.1% | 15 ppm | 1.9% | AEPD | remainder | 5.5 | 100% | 50 C. | 46.1 | 0.8 | <1 | <1 | 57.6 |
| | | | | | 3.0% | | | | | | | | | |
| FE-5 | 27% | 0.1% | 15 ppm | 1.9% | AMP | remainder | 5.5 | 100% | 50 C. | 36.4 | 0.6 | <1 | <1 | 60.7 |
| | | | | | 2.3% | | | | | | | | | |
| FE-6 | 27% | 0.1% | 15 ppm | 1.9% | MEA | remainder | 5.5 | 100% | 50 C. | 88.5 | 5.1 | <1 | <1 | 17.4 |
| | | | | | 1.6% | | | | | | | | | |
| FE-7 | 27% | 0.1% | 15 ppm | 1.9% | APD | remainder | 5.5 | 100% | 50 C. | 89.7 | 3.1 | <1 | <1 | 28.9 |
| | | | | | 2.3% | | | | | | | | | |
| FE-8 | 27% | 0.1% | 15 ppm | 2.0% | Tris | remainder | 6.5 | 100% | 50 C. | 77.7 | 2.8 | <1 | <1 | 27.8 |
| | | | | | 3.6% | | | | | | | | | |
| FE-9 | 27% | 0.1% | 15 ppm | 1.0% | Tris | remainder | 7.6 | 100% | 50 C. | 101.6 | 4.3 | <1 | <1 | 23.6 |
| | | | | | 3.6% | | | | | | | | | |
| FE-10 | 27% | 25 ppm | 15 ppm | 1.9% | Tris | remainder | 5.0 | 100% | 50 C. | 115.3 | 6.8 | <1 | <1 | 16.9 |
| | | | | | 2.8% | | | | | | | | | |
| FE-11 | 27% | 25 ppm | 15 ppm | 1.9% | Tris | remainder | 5.0 | 100% | 41 C. | 51.0 | 0.2 | <1 | <1 | 251 |
| | | | | | 2.8% | | | | | | | | | |
| CE-1 | 27% | 0.1% | 15 ppm | 1.9% | NH₄OH | remainder | 5.5 | 100% | 50 C. | 197.7 | 102.9 | <1 | <1 | 1.9 |
| | | | | | 0.6% | | | | | | | | | |
| CE-2 | 27% | 0.1% | 15 ppm | 1.9% | TMAH | remainder | 5.5 | 100% | 50 C. | 9.6 | 1.0 | <1 | <1 | 9.6 |
| | | | | | 2.3% | | | | | | | | | |
| CE-3 | 27% | 0.1% | 15 ppm | 1.9% | DBU | remainder | 5.5 | 100% | 50 C. | 21.4 | 2.1 | <1 | <1 | 10.2 |
| | | | | | 5.5% | | | | | | | | | |
| CE-4 | 27% | 0.1% | 15 ppm | 1.9% | DAMP | remainder | 5.5 | 100% | 50 C. | 129.8 | 32 | <1 | <1 | 4.1 |
| | | | | | 1.9% | | | | | | | | | |

FE = formulation example (formulation of the disclosure);
CE = comparative example;
BECl = benzethonium chloride;
CHG = chlorhexidine digluconate;
HEDP = 1-hydroxyehylidene-1,1-diphosphonic acid;
Tris = tris(hydroxymethyl)aminomethane;
AMPD = 2-amino-2-methyl-1,3-propanediol;
AEPD = 2-Amino-2-ethyl-1,3-propanediol;
AMP = 2-amino-2-methyl-2-propanol;
MEA = monoethanolamine;
APD = 2-hydroxy-3-aminopropanol;
TMAH = Tetramethylammonium hydroxide;
DBU = 1,8-Diazabicyclo[5.4.0]undec-7-ene;
DAMP = 1,5-Diamino-2-methylpentane.

### General Procedure 4 (Bath-Life Test)

Etching rates for TiN features (e.g., a TiN film) according to General Procedure 3, were compared between freshly prepared compositions and compositions aged 72 hrs at 41° C. (FE-11) or 50° C. (others). Etching temperature was 41° C. (FE-11) or 50° C. (others). Table 2 presents the results from this study.

TABLE 2

| | FE-1 | FE-2 | FE-8 | FE-9 | FE-11 |
|---|---|---|---|---|---|
| pH | 5.0 | 5.5 | 6.5 | 7.6 | 5.0 |
| Process temperature | 50° C. | 50° C. | 50° C. | 50° C. | 41° C. |
| TiN ER (Å/min) | 47.1 | 61.8 | 77.7 | 101.6 | 50.2 |
| (composition | | | | | |
| freshly prepared) | | | | | |
| TiN ER (Å/min) | 46.8 | 40.8 | 52.2 | 27.8 | 51.5 |
| (composition | | | | | |
| aged 24 hrs) | | | | | |
| TiN ER (Å/min) | 41.0 | ND | ND | ND | 51.4 |
| (composition | | | | | |
| aged 72 hrs) | | | | | |
| ER ratio freshly | 99% | 66% | 67% | 27% | 103% |
| prepared/aged 24 hrs | | | | | |
| ER ratio freshly | 87% | ND | ND | ND | 103% |
| prepared/aged 72 hrs | | | | | |

As demonstrated in Table 2, compositions with a pH of about 5 to about 5.5 have improved bath-life performance when compared to compositions with pH greater than 6. Also lowering process temperature from 50° C. to 41° C. extended bath-life performance significantly.

While the invention has been described in detail with reference to certain embodiments thereof, it will be understood that modifications and variations are within the spirit and scope of that which is described and claimed.

What is claimed is:

1. An etching composition, comprising:
1) at least one oxidizing agent;
2) at least one chelating agent;
3) at least one metal corrosion inhibitor;
4) at least one pH adjusting agent, wherein the pH adjusting agent is aminoalcohol;
and
5) water;
wherein the composition has a pH less than about 7.

2. The composition of claim 1, wherein the at least one oxidizing agent comprises hydrogen peroxide.

3. The composition of claim 1, wherein the composition comprises from about 10 percent to about 40 percent by weight of the at least one oxidizing agent.

4. The composition of claim 1, wherein the at least one chelating agent comprises an organophosphorus compound.

5. The composition of claim 4, wherein the organophosphorus compound is a phosphonic acid.

6. The composition of claim 5, wherein the phosphonic acid is 1-hydroxyethane-1,1-diphosphonic acid.

7. The composition of claim 1, wherein the composition comprises from about 0.1 percent to about 5 percent by weight of the at least one chelating agent.

8. The composition of claim 1, wherein the at least one metal corrosion inhibitor comprises a quaternary ammonium salt.

9. The composition of claim 8, wherein the quaternary ammonium salt is benzethonium chloride.

10. The composition of claim 1, wherein the at least one metal corrosion inhibitor comprises a biguanide.

11. The composition of claim 10, wherein the biguanide is chlorhexidine digluconate.

12. The composition of claim 1, wherein the composition comprises from about 0.0001 percent to about 1 percent by weight of the at least one metal corrosion inhibitor.

13. The composition of claim 1, wherein the aminoalcohol bears one hydroxyl moiety, two hydroxyl moieties, or three hydroxyl moieties.

14. The composition of claim 1, wherein the aminoalcohol is monoethanolamine, diethanolamine, triethanolamine, 4-amino-1-butanol, 2-(2-aminoethoxy)ethanol, 3-amino-1-propanol, 2-amino-1-propanol, 1-amino-2-propanol, 2-amino-1-butanol, 2-amino-2-methyl 1-propanol, 2-(2-aminoethoxy)propanol, 5-amino-1-pentanol, 2-amino-1-pentanol, 2-amino-3-methyl-1-butanol, 2-amino-1-hexanol, isoleucinol, leucinol, 1-amino-1-cyclopentanemethanol, trans-2-aminocyclohexanol, trans-4-aminocyclohexanol, 3-aminomethyl-3,5,5-trimethylcyclohexanol, 1-aminomethyl-1-cyclohexanol, 6-amino-1-hexanol, 6-amino-2-methyl-2-heptanol, 4-amino-4-(3-hydroxypropyl)-1,7-heptanediol, serinol, 3-amino-1,2-propanediol, N-(3-aminopropyl)-diethanolamine, 2-amino-2-ethyl-1,3-propanediol, 2-amino-2-methyl-1,3-propanediol, tris(hydroxymethyl)aminomethane, 1-amino-1-deoxy-D-sorbitol, or (hydroxyethoxyethyl)amine.

15. The composition of claim 1, wherein the composition comprises from about 50 percent to about 80 percent of water.

16. The composition of claim 1, further comprising a fluorine compound.

17. The composition of claim 16, wherein the fluorine compound is HF.

18. The composition of claim 1, wherein the pH is between about 4.5 and about 6.0.

19. A method, comprising contacting a semiconductor substrate containing TiN features with a composition of claim 1, thereby removing the TiN features.

20. The method of claim 19, further comprising rinsing the semiconductor substrate with a rinse solvent after the contacting step.

21. The method of claim 20, further comprising drying the semiconductor substrate after the rinsing step.

22. The method of claim 19, wherein the method does not substantially remove W, Co, SiN, or Cu in the semiconductor substrate.

23. The method of claim 19, wherein the method does not substantially remove W.

24. An article formed by the method of claim 19, wherein the article is a semiconductor device.

25. The article of claim 24, wherein the semiconductor device is an integrated circuit.
